(19) United States
(12) Patent Application Publication
(10) Pub. No.: US 2015/0295117 A1
(43) Pub. Date: Oct. 15, 2015

(54) INFRARED PHOTOVOLTAIC DEVICE

(71) Applicants: Jose Briceno, Tokyo-to (JP); Koji MATSUMARU, Nagaoka-Shi (JP)

(72) Inventors: Jose Briceno, Tokyo-to (JP); Koji MATSUMARU, Nagaoka-Shi (JP)

(21) Appl. No.: 14/217,078

(22) Filed: Mar. 17, 2014

Related U.S. Application Data
(63) Continuation-in-part of application No. 13/844,686, filed on Mar. 15, 2013.
Application No. 13/844,686 is a continuation-in-part of application No. 13/844,298, filed on Mar. 15, 2013, now Pat. No. 8,952,246.
Application No. 13/844,298 is a continuation-in-part of application No. 13/844,428, filed on Mar. 15, 2013.
Application No. 13/844,428 is a continuation-in-part of application No. 13/844,521, filed on Mar. 15, 2013, now Pat. No. 9,099,578.
Application No. 13/844,521 is a continuation-in-part of application No. 13/844,747, filed on Mar. 15, 2013.
(60) Provisional application No. 61/800,912, filed on Mar. 15, 2013.
(60) Provisional application No. 61/800,800, filed on Mar. 15, 2013.
(60) Provisional application No. 61/801,019, filed on Mar. 15, 2013.
(60) Provisional application No. 61/801,145, filed on Mar. 15, 2013.
(60) Provisional application No. 61/801,244, filed on Mar. 15, 2013.
(60) Provisional application No. 61/761,342, filed on Feb. 6, 2013.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.
(60) Provisional application No. 61/619,410, filed on Apr. 2, 2012.
(60) Provisional application No. 61/722,693, filed on Nov. 5, 2012.
(60) Provisional application No. 61/655,449, filed on Jun. 4, 2012.
(60) Provisional application No. 61/738,375, filed on Dec. 17, 2012.

(51) Int. Cl. H01L 31/078; H01L 31/18; H01L 31/0216; H01L 31/0312; H01L 31/0224

(52) U.S. Cl. CPC H01L 31/078; H01L 31/0312; H01L 31/022483; H01L 31/022425; H01L 31/02168; H01L 31/1884; H01L 31/18

(57) ABSTRACT

A hybrid photovoltaic (PV) device according comprises a semiconductor substrate, a semiconductor photovoltaic (PV) layer on one side of said substrate, a metal layer on top of said PV layer, a first electrode layer on top of said metal layer, and a bottom metal electrode on the opposite side of said substrate from said PV layer, wherein said metal layer forms a Shottcky junction between said metal layer and said PV layer. Because of existence of the Shottcky junction, the PV cell permits light to electricity conversion over a wide-range of light wavelengths, from visible light (between 350 nm to 900 nm wavelength) to infrared light (over 900 nm wavelength). Also described is a method for manufacturing a hybrid PV device. The method of manufacturing comprises performing the steps of: cleaning a semiconductor substrate; introducing an inert gas under vacuum and a high temperature to form a semiconductor PV layer having a high resistivity on the top surface of said substrate; forming a metal layer over said PV layer to create a Shottcky junction between said metal layer and said PV layer; forming a transparent layer over the top of said metal layer; and forming a metal bottom electrode on the bottom surface of said substrate.

### CROSS-REFERENCE TO RELATED APPLICATIONS

This application claims the benefit of U.S. application Ser. No. 13/844,686, filed Mar. 15, 2013 (Attorney Docket No. 44671-047 (P7)); U.S. Provisional Application No. 61/761,342, filed Feb. 6, 2013 (Attorney Docket No. 44671-047 (P7)); U.S. application Ser. No. 13/844,298, filed Mar. 15, 2013 (Attorney Docket No. 44671-033 (P2)); U.S. Provisional Application No. 61/619,410, filed Apr. 2, 2012 (Attorney Docket No. 44671-033 (P2)); U.S. application Ser. No. 13/844,428, filed Mar. 15, 2013 (Attorney Docket No. 44671-034 (P3)); U.S. Provisional Application No. 61/722,693, filed Nov. 5, 2012 (Attorney Docket No. 44671-034 (P3)); U.S. application Ser. No. 13/844,521, filed Mar. 15, 2013 (Attorney Docket No. 44671-035 (P4)); U.S. Provisional Application No. 61/655,449, filed Jun. 4, 2012 (Attorney Docket No. 44671-035 (P4)); U.S. application Ser. No. 13/844,747, filed Mar. 15, 2013 (Attorney Docket No. 44671-038 (P5)); U.S. Provisional Application No. 61/738,375, filed Dec. 17, 2012 (Attorney Docket No. 44671-038 (P5)); U.S. Provisional Application No. 61/715,283, filed Oct. 17, 2012 (Attorney Docket No. 44671-041 (P12)); U.S. Provisional Application No. 61/715,286, filed Oct. 18, 2012 (Attorney Docket No. 44671-043 (P13)); U.S. Provisional Application No. 61/715,287, filed Oct. 18, 2012 (Attorney Docket No. 44671-044 (P14)); U.S. Provisional Application No. 61/801,019, entitled Manufacturing Equipment for Photovoltaic Devices, filed 15 Mar. 2013 (Attorney Docket No. 44671-050 (P 32)); U.S. Provisional Application No. 61/800,912, entitled Infrared Photovoltaic Device, filed 15 Mar. 2013 (Attorney Docket No. 44671-049 (P 10)); U.S. Provisional Application No. 61/800,800, entitled Hybrid Transparent Electrode Assembly for Photovoltaic Cell Manufacturing, filed 15 Mar. 2013 (Attorney Docket No. 44671-048 (P23)); U.S. Provisional Application No. 61/801,145, entitled PIN Photo-voltaic device and Manufacturing Method, filed 15 Mar. 2013 (Attorney Docket No. 44671-051 (P 17)), and U.S. Provisional Application No. 61/801,244, entitled Infrared Photo-voltaic device and Manufacturing Method, filed 15 March 2013 (Attorney Docket No. 44671-052 (P36)), the entireties of which are incorporated by reference as if fully set forth herein.

US. patent application Ser. No. 13/844,686, filed 15 Mar. 2013 (docket number P7, sub case 003); the entirety of which is incorporated by reference as if fully set forth herein.

### FIELD OF THE INVENTION

The present invention relates to photovoltaic devices, and in particular, a photovoltaic device structure with improved photovoltaic properties and a simplified method of manufacture.

### BACKGROUND OF THE INVENTION

A solar cell (also called a photovoltaic cell) is an electrical device that converts the energy of light directly into electricity by the photovoltaic effect. Prior art solar cell technology typically utilizes crystalline silicon as a main ingredient, and in some other cases, inexpensive poly-crystalline silicon or other compound semiconductors. In addition, other technologies use organic materials for the so-called dye-sensitized solar cells. Prior art crystalline silicon solar cells are often fabricated by forming a high concentration n-type layer on a p-type silicon substrate. This high concentration n-type layer is generally formed by a process of ion implantation, or diffusion, introducing the n-type dopant phosphorous, to form a PN junction, followed by an annealing process. Once the PN junction is so formed, anode and cathode electrodes are formed to complete the photovoltaic cell.

The conventional methods for manufacturing photovoltaic materials also require a multi-step process, or different processes, with each step possibly taking place at a different apparatus and at different times, and requiring its own management and resources. It is highly desirable to have a manufacturing process for photovoltaic (PV) materials that reduces the number of necessary processes or steps to reduce costs.

Currently available photovoltaic technology generally provides electric energy converted from sunlight only during the day. In addition, these legacy PV cells show best performance when the sun is high in the sky, and cell efficiency or performance drops drastically during morning and evening hours, as well as during overcast days. During cloudy or overcast days, the amount of energy that reaches solar cells is limited, since light is filtered by the cloud cover, therefore reducing the total amount of electric power generated by such solar cells in these conditions.

Since prior art silicon-based PV cells are unable to produce electricity by capturing infrared light, the performance of such cells will drop considerable in bad weather, despite the fact that the amount of infrared light (over 900 nm wavelength) reaching the earth's surface is practically unaffected by the weather or the amount of cloud cover. To overcome this issue, there are some prior art PV technologies able to capture infrared light, but these technologies use very expensive and toxic materials such as arsenic (As) during manufacture.

It is highly desirable to have an inexpensive manufacturing process for photovoltaic cell design that permits light to electricity conversion of a wide-range of light wavelengths, from the so-called visible light range to the infrared light range, without the need for toxic materials during processing.

### BRIEF SUMMARY OF THE INVENTION

Preferred embodiments of the present invention provide a hybrid PV solar cell, one that generates electricity from both visible and infrared light (also called the infrared PV cell below), and a method of manufacturing the cell. The method of manufacturing the PV device is preferably a toxic material free process, which lowers the overall manufacturing cost.

In one embodiment, an infrared photovoltaic device according to the claimed invention comprises a semiconductor substrate, a semiconductor photovoltaic (PV) layer on one side of said substrate, a metal layer on top of said PV layer, a first electrode layer on top of said metal layer, and a bottom metal electrode on the opposite side of said substrate from said PV layer, wherein said metal layer forms a Shottcky junction between said metal layer and said PV layer.

Because of the existence of the Shottcky junction, the PV cell of the present invention permits light to electricity conversion over a wide-range of light wavelengths, from the so-called visible light (between 350 nm to 900 nm wavelength) to the infrared light (over 900 nm wavelength). The PV structure only absorbs energy within the visible light spectrum, while the semiconductor/metal Shottcky interface absorbs energy in the infrared light wavelength or higher.

In one embodiment, a method of manufacturing a photovoltaic (PV) device having a semiconductor substrate comprising performing the steps of: cleaning said substrate; introducing an inert gas under vacuum and a high temperature to form a semiconductor PV layer having a high resistivity on the top surface of said substrate; forming a metal layer over said PV layer to create a Shottcky junction between said metal layer and said PV layer; forming a transparent layer over the top of said metal layer; and forming a metal bottom electrode on the bottom surface of said substrate.

In one embodiment, the present invention discloses the design and method of fabrication of a high-performance solar cell, using semiconductor silicon and metal in a heterojunction design that is able to transform simultaneously white light and infrared light into electricity, and wherein the solar cell is produced by an inexpensive manufacturing method.

In one embodiment, the heterojunction cell is formed by adding a metal layer on top of a high resistivity silicon semiconductor layer on top of a silicon substrate. While the high resistivity layer captures white light spectrum, the metal semiconductor Schottky junction captures infrared light, making the cell able to produce electricity not only in normal daylight conditions, but also during overcast days, morning or evening times, or even by absorbing ambient heat.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a cross-sectional view of an infrared PV device 100 during one stage of manufacture according to one embodiment after the PV device has been formed.

FIG. 2 A is a cross-sectional view of another infrared PV device 200 and FIG. 2 B is a partial circuit diagram 220 showing the equivalent circuit elements formed by the semiconductor bulk layer, the PV structure, and the metal layer according to one embodiment of the present invention.

FIG. 3 is a flow diagram illustrating an example of the steps for manufacturing the PV device 200 shown in FIG. 2.

### DETAILED DESCRIPTION OF PREFERRED EMBODIMENTS OF THE INVENTION

In the following description, numerous specific details have been set forth to provide a more thorough understanding of embodiments of the present invention. It will be appreciated however, by one skilled in the art, that embodiments of the invention may be practiced without such specific details or with different implementations for such details. Additionally, some well-known structures have not been shown in detail to avoid unnecessarily obscuring the present invention.

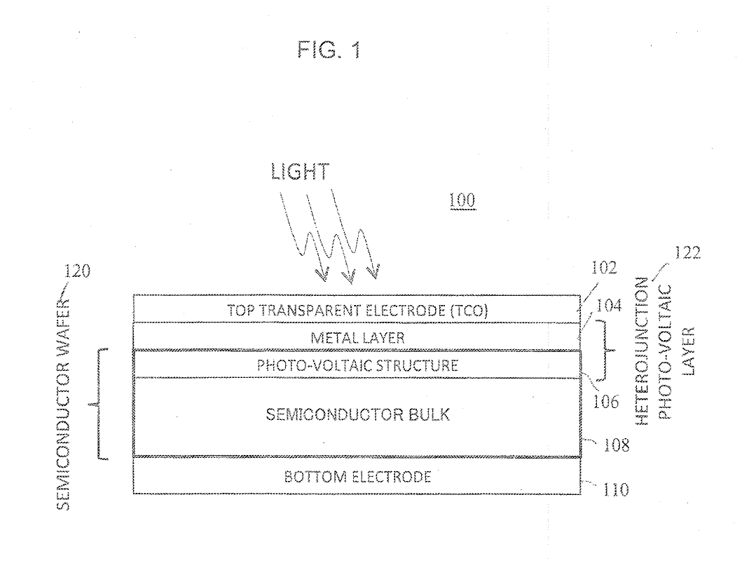

FIG. 1 is a cross-sectional view of infrared PV cell 100 during one stage of the manufacturing process according to one embodiment of the present invention. Device 100 is constructed from a semiconductor substrate or semiconductor bulk layer 108 on a semiconductor wafer 120. First, a PV structure 106 is formed on the surface of the semiconductor bulk layer 108 upon the heat treatment of this layer. The PV layer 106 has a resistivity that is typically much higher than the semiconductor substrate 108, and it functions to capture light in the visible spectrum. A metal layer 104 is formed on top of PV layer 106. The junction between metal layer 104 and PV layer 106 creates a Schottky junction that functions to capture infrared light. The heterojunction photovoltaic layer 122 therefore comprises PV layer 106 and the metal-semiconductor Schottky junction.

As also seen in FIG. 1, a first electrode layer 102 is formed on top of metal layer 104. It is preferably a transparent conductive oxide (TCO) electrode. Electrode layer 102 allows light to penetrate into the hybrid PV cell 100. Layer 102 may be formed by any means known in the art including impurity diffusion or doping of the semiconductor substrate 108. Lastly, a bottom electrode 110 is formed on the bottom surface of the semiconductor bulk layer 108.

The above-described hybrid design enables PV cell 100 to transform both visible light and infrared light simultaneously into electricity.

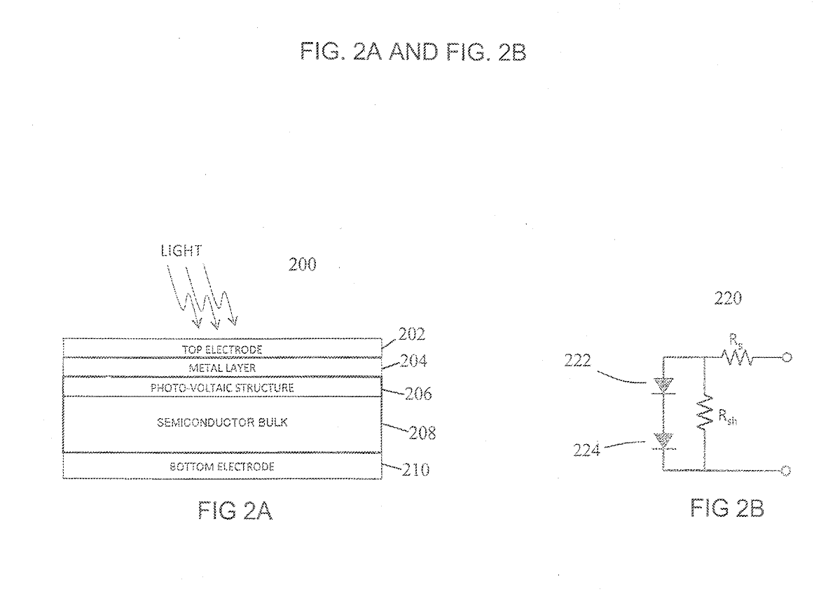

As seen in FIG. 2, the hybrid PV cell 200 of the present invention comprises two main components. A semiconductor photovoltaic layer that has silicon material having a resistivity different from that of the silicon semiconductor substrate, and a metal-semiconductor Schottky junction as discussed above. Referring to FIG. 2B, a partial circuit diagram 220 is shown which illustrates the equivalent circuit elements formed by the semiconductor bulk layer 208, the PV structure 206, and the metal layer 204. As is seen, the junction between the semiconductor bulk layer 208 and the PV structure 206 creates a first equivalent diode 222, and the Shottcky junction between the PV structure 206 and metal layer 204 creates a second equivalent diode 224. As illustrated in FIG. 2B, both photovoltaic junctions 122 and 124 are aligned so the junctions compensate each other, improving overall cell performance, in addition to achieving infrared light PV capabilities.

The junction between the semiconductor substrate 208 and PV structure 206 layers reacts to the visible-light spectrum, while the Schottky junction between the metal layer 204 and PV structure 206 reacts to the infrared light spectrum. These two combined junctions make a very powerful hybrid solar cell, capable of producing electricity from light of a very wide spectrum, from the visible through the infrared wavelengths.

As with the PV device shown in FIG. 1, the PV device 200 in FIG. 2 also includes a transparent top electrode 202 formed on top of the cell 200, allowing light to penetrate both photovoltaic junctions. A bottom ohmic electrode 210 is placed on the opposite side of the semiconductor substrate 208 from the PV structure 206 and metal layer 204.

### Fabrication Process

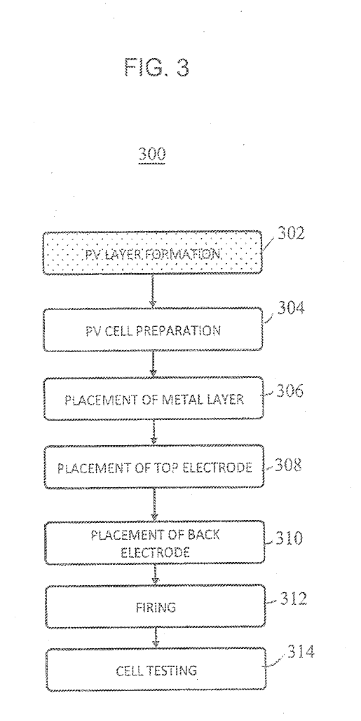

FIG. 3 is a flow diagram illustrating an example of the steps for manufacturing the PV device 200 shown in FIG. 2. The process shown in FIG. 3 begins with formation of the PV structure 206 on top of the semiconductor bulk layer 208 by heat treatment at step 302. The PV cell 200 is cleaned at step 304. At step 306, metal layer 204 is added to form a Shottcky junction between the metal layer and the PV structure 206. The top electrode 202 is then placed on the top of metal layer 204 at step 308 and a bottom or back electrode is formed on the opposite side of the semiconductor bulk layer 208 at step 310.

PV cell preparation step 304 is a wafer cleaning step that preferably uses a neutral detergent, and an organic neutral detergent for removal of the abrading agent on the wafer.

Formation of metal layer 306 preferably is by deposition of the metal layer on the wafer by sputtering. Placement of the top electrode 202 at step 308 is preferable performed by depositing a transparent oxide layer by sputtering followed by optional steps of applying an anti-reflection coat and a silver paste bus-bar by screen printing. Placement of back electrode 210 at step 310 is preferably by screen printing an aluminum paste. The last step, at 312, is to heat the resulting PV device to 500° K to remove binder solvent of the silver paste.

Typically, cell testing is performed on the PV device once it has been manufactured and this is shown at step 314. This is not part of the fabrication process. However, the PV device is usually run through a series of tests to determine its overall efficiency at this point.

Turning again more specifically to the manufacture of a PV device according to one embodiment of the invention, as described above, to begin the process a 6-inch n-type silicon single crystal substrate wafer may be used as semiconductor bulk layer 208. This substrate preferably has a resistivity of 1 to 5 (Ωcm), (100) crystal orientation. Substrate 208 is first cleaned by the use of a typical RCA cleaning method.

The substrate cleaning is performed in the following steps: removing organic material using sulfuric acid-hydrogen peroxide water cleaning for ten minutes at 350 K; pure water cleaning followed by nitrogen blow drying with infrared and ultraviolet light drying; cleaning using a 0.5% hydrofluoric acid solution; cleaning by ammonium-hydrogen peroxide water at 350 K for 10 minutes; removing heavy metal contamination by 80° C. hydrochloric acid-hydrogen peroxide water cleaning for ten minutes after pure water rinsing; and, lastly, pure water cleaning and nitrogen gas drying followed by paper IPA drying.

Next, a high resistivity layer, PV structure 206, which is a first layer of the photovoltaic generation layer, is preferably formed by the following method.

Inert gas is introduced into a quartz boat containing the semiconductor bulk wafer 208, which had been previously vacuumed to approximately 1E-3 Pa. The quartz boat is then heated and kept at a predetermined annealing temperature (800K or more) for 30 minutes.

While vacuum of approximately 1E-3 Pa was used in the present example, the degree of the vacuum may not be specified in particular at a vacuum of approximately 20 Pa or lower. Further, while argon gas was used as the inert gas in the present example, another inert gas such as helium gas, and the like, or a mixture of these inert gases may be used.

A variety of heating methods can be used to form intrinsic silicon layer 9, including but not limited to infrared heating, laser heating, and hot-wall furnace heating. In some embodiments, the particular heating methods used for treating the substrate layer have an effect on photovoltaic performance of the photovoltaic cell. In some embodiments, the cooling rate after the heating stage is a crucial factor to photovoltaic cell fabrication, whereas the heating rate is a less crucial factor to photovoltaic cell fabrication. Maximum photovoltaic cell performance can be obtained at heating temperatures above 1500° K, at heating times above 5 minutes, at approximately 1×10⁻³ Pa. The overall parameters used during heating step include temperatures ranging from 852 1700° Kelvin, heating times from one to 600 min., atmospheres from vacuum, argon, nitrogen or other inert gas at temperatures up to 1 atm. After the heating process is completed, the substrate is transformed into a photovoltaic semiconductor material having a high-resistivity layer therein.

Next, the substrate 208 is preferably cleaned by the use of a typical RCA cleaning method, similar to the one mentioned above.

A 5 nm layer of gold is then formed on the PV structure by means of a sputtering method to form metal layer 204. While a sputtering method was used in this example, any other method may be utilized to fabricate the thin metal layer on top of the semiconductor photovoltaic layer 206. While the thickness of 5 nm is used in the present example, the thickness is not limited to 5 nm, as long as it is sufficiently thin enough to allow light transmission from transparent electrode 202 to the PV structure 206.

Next, a 150 nm thick ZnO transparent conductive film is formed on top of metal layer 204 by a sputtering method.

An optional silver paste bus-bar is formed on top of the ZnO layer to improve overall top electrode electrical properties. Placement of the bus-bar is preferably performed by screen printing method.

While ZnO was used in the present example, another transparent conductive film such as ITO, SnO2, FTO, AZO, GZO, IZO, TNO, ATO, FeO2, and NbO2, or a stacked structure thereof, may be used, and the transparent conductive film may be formed by PLD, MOCVD, a coating method, or the like, and not limited to the sputtering method.

Next, a silicon nitride film is preferably formed consecutively as an anti-reflection film. Lastly, a metal layer of aluminum is added to form bottom electrode 210. This metal layer is added by screen printing on the opposite surface of substrate 208 from the PV layer 206. Lastly, this layer is heated at 550 K to remove the binder, and complete the solar cell 200 construction.

While a single crystal silicon having 1 to 5 (Ω-cm) and orientation (100) is used for the silicon substrate in the present example, the face orientation may be (110) or (111), and solar grade silicon or poly-crystalline silicon may be used. When a silicon substrate having a different resistivity is used, it is necessary to change heating temperature and time.

While a gold metal layer is used in the present example, any metal having a work function greater than that of n-type silicon semiconductor may be used, such as platinum (Pt), tungsten (W), nickel (Ni), iron (Fe), and palladium (Pd).

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

We claim:

1. An infrared photovoltaic device comprising a semiconductor substrate, a semiconductor photovoltaic (PV) layer on one side of said substrate, a metal layer on top of said PV layer, a first electrode layer on top of said metal layer, and a bottom metal electrode on the opposite side of said substrate from said PV layer, wherein said metal layer forms a Shottcky junction between said metal layer and said PV layer.

2. The device of claim 1 wherein said semiconductor substrate is an n-type silicon single crystal substrate, and wherein said n-type silicon substrate has a resistivity in the range of about 1 to about five ohm centimeter (Ω·cm).

3. The device of claim 1 wherein said TCO is selected from the group consisting of ZnO, ITO, ACO, GZO, IZO, and NbO2.

4. The device of claim 3 wherein said TCO is ZnO.

5. The device of claim 1 wherein said metal layer has a thickness that allows light transmission.

6. The device of claim 5 wherein said metal layer has a thickness of 5 nm.

7. The device of claim 6 wherein said metal layer is selected from the group consisting of gold, platinum, tungsten, nickel, iron, palladium, and mixtures thereof.

8. The device of claim 1 wherein said metal layer is gold

9. The device of claim 1 wherein said bottom electrode is a layer of aluminum.

10. The device of claim 1 wherein said bottom metal electrode makes an ohmic contact with said semiconductor substrate.

11. The device of claim 1 further comprising an anti-reflection film on top of the first electrode layer.

12. The device of claim 11 wherein said anti-reflection film is silicon nitride.

13. A method of manufacturing a photovoltaic (PV) device having a semiconductor substrate comprising performing the steps of: cleaning said substrate; introducing an inert gas under vacuum and a high temperature to form a semiconductor PV layer having a high resistivity on the top surface of said substrate; forming a metal layer over said PV layer to create a Shottcky junction between said metal layer and said PV layer; forming a transparent layer over the top of said metal layer; and forming a metal bottom electrode on the bottom surface of said substrate.

14. The method of claim 13 wherein said substrate is an n-type silicon single crystal substrate having a resistivity in the range of about 1 to about five ohm centimeter (Ω·cm).

15. The method of claim 13 wherein said semiconductor PV layer has a thickness of at least 5 nanometers (nm).

16. The method of claim 13 further comprising forming an anti-reflective coating on top of said transparent electrode layer, wherein said anti-reflective coating is silicon nitride.

17. The method of claim 13 wherein said transparent electrode layer is a transparent conductive oxide (TCO) film selected from the group consisting of ZnO, ITO, ACO, GZO, IZO, and NbO2.

18. The method of claim 17 wherein said TCO film is ZnO.

19. The method of claim 13 wherein said bottom metal electrode is aluminum.
